(19) United States
(12) Patent Application Publication
(10) Pub. No.: US 2026/0121654 A1
(43) Pub. Date: Apr. 30, 2026

(54) Differential slope analog-to-digital conversion apparatus and method

(71) Applicant: REALTEK SEMICONDUCTOR CORPORATION, HSINCHU (TW)

(72) Inventors: CHIA-WEI KAO, Hsinchu (TW); SHIH-HSIUNG HUANG, Hsinchu (TW)

(21) Appl. No.: 19/329,909

(22) Filed: Sep. 16, 2025

(30) Foreign Application Priority Data
Oct. 25, 2024 (TW) 113140720

(51) Int. Cl. H03M 1/44

(52) U.S. Cl. CPC H03M 1/442

(57) ABSTRACT

A differential slope analog-to-digital conversion apparatus is provided. A first and a second capacitors perform sampling according to a pair of analog input signals in a sampling time. A ramp voltage generation circuit performs a positive slope voltage feeding on the first capacitor according to a first positive slope, a negative slope voltage feeding on the second capacitor according to a first negative slope in a first feeding time, the positive slope voltage feeding on the second capacitor according to a second positive slope and the negative slope voltage feeding on the first capacitor according to a second negative slope in a second feeding time. A comparison circuit receives a first and a second voltages from the first and the second capacitors to perform comparison to generate a comparison result. A counting circuit performs counting according to the comparison result to generate a digital output signal.

### BACKGROUND OF THE INVENTION

### 1. Field of the Invention

The present invention relates to a differential slope analog-to-digital conversion apparatus and a differential slope analog-to-digital conversion method.

### 2. Description of Related Art

An analog-to-digital converter is a circuit that converts a continuous signal in the analog form to a discrete signal in the digital form. The analog-to-digital converter may be implemented by using different methods, in which a slope analog-to-digital conversion (ADC) apparatus is one of them that performs comparison between an input signal and a ramp signal and performs counting accordingly to generate the digital signal.

However, when the time required for the ramp signal to reach a certain level is too short, the required slope is steep such that the design complexity of a ramp signal generation circuit used in the slope analog-to-digital conversion apparatus increases.

### SUMMARY OF THE INVENTION

In consideration of the problem of the prior art, an object of the present invention is to supply a differential slope analog-to-digital conversion apparatus and a differential slope analog-to-digital conversion method.

The present invention discloses a differential slope analog-to-digital conversion apparatus that includes a first capacitor, a second capacitor, a ramp voltage generation circuit, a comparison circuit and a counting circuit. The first capacitor is configured to perform sampling according to a pair of analog input signals in a sampling time. The second capacitor is configured to perform sampling according to the pair of analog input signals in the sampling time. The ramp voltage generation circuit is configured to perform a positive slope voltage feeding on the first capacitor according to a first positive slope and perform a negative slope voltage feeding on the second capacitor according to a first negative slope in a first feeding time and perform the positive slope voltage feeding on the second capacitor according to a second positive slope and perform the negative slope voltage feeding on the first capacitor according to a second negative slope in a second feeding time, in which the first feeding time and the second feeding time proceed with the sampling time in turn in an interlaced manner. The comparison circuit is configured to receive a first voltage from the first capacitor and a second voltage from the second capacitor in the first feeding time and the second feeding time to perform comparison to generate a comparison result. The counting circuit is configured to perform counting according to the comparison result to generate a digital output signal.

The present invention also discloses a differential slope analog-to-digital conversion method that includes steps outlined below. Sampling is performed according to a pair of analog input signals in a sampling time by a first capacitor. Sampling is performed according to the pair of analog input signals in the sampling time by a second capacitor. A positive slope voltage feeding is performed on the first capacitor according to a first positive slope and a negative slope voltage feeding is performed on the second capacitor according to a first negative slope in a first feeding time by a ramp voltage generation circuit. The positive slope voltage feeding is performed on the second capacitor according to a second positive slope and the negative slope voltage feeding is performed on the first capacitor according to a second negative slope in a second feeding time by the ramp voltage generation circuit, in which the first feeding time and the second feeding time proceed with the sampling time in turn in an interlaced manner. A first voltage is received from the first capacitor and a second voltage is received from the second capacitor in the first feeding time and the second feeding time to perform comparison to generate a comparison result by a comparison circuit. Counting is performed according to the comparison result to generate a digital output signal by a counting circuit.

These and other objectives of the present invention will no doubt become obvious to those of ordinary skill in the art behind reading the following detailed description of the preferred embodiments that are illustrated in the various figures and drawings.

### BRIEF DESCRIPTION OF THE DRAWINGS

FIG. 1A to FIG. 1C illustrate circuit diagrams of a differential slope analog-to-digital conversion apparatus operating under different operation times according to an embodiment of the present invention.

FIG. 2 illustrates a waveform diagram of signals related to the operation of the differential slope analog-to-digital conversion apparatus in FIG. 1A to FIG. 1C according to an embodiment of the present invention.

FIG. 3 illustrates a waveform diagram of a first connection voltage of the first connection node, a second connection voltage of the second connection node, the first voltage of the second terminal of the first capacitor and the second voltage of the fourth terminal of the second capacitor in FIG. 1A to FIG. 1C according to an embodiment of the present invention.

FIG. 4 illustrates a flow chart of a differential slope analog-to-digital conversion method according to an embodiment of the present invention.

### DETAILED DESCRIPTION OF THE PREFERRED EMBODIMENTS

An aspect of the present invention is to provide a differential slope analog-to-digital conversion apparatus and a differential slope analog-to-digital conversion method to operate in a differential form such that two terminals of a comparison circuit receive ramp voltages respectively having a positive slope and a negative slope to obtain an equivalently larger slope to allow analog input signals approximating each other accordingly. The design complexity of a ramp voltage generation circuit can therefore be reduced.

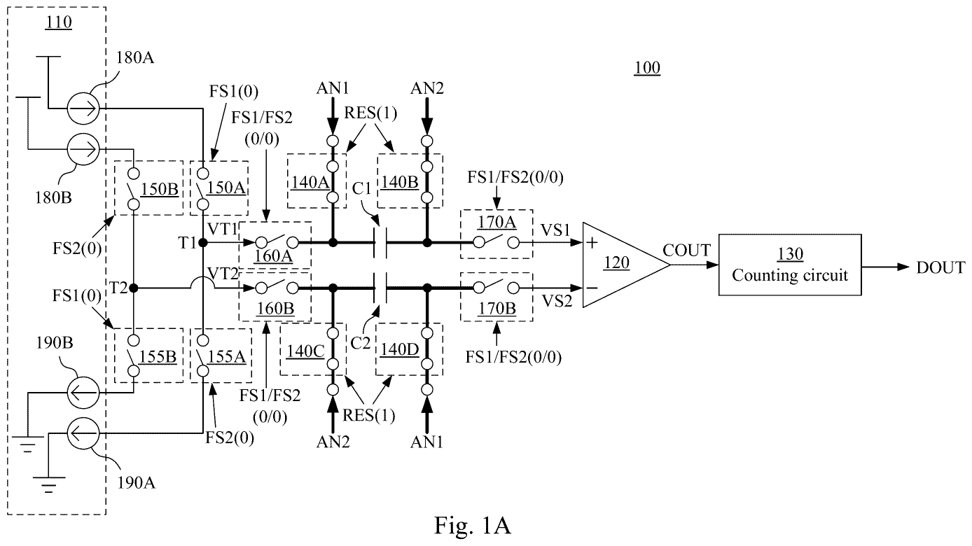

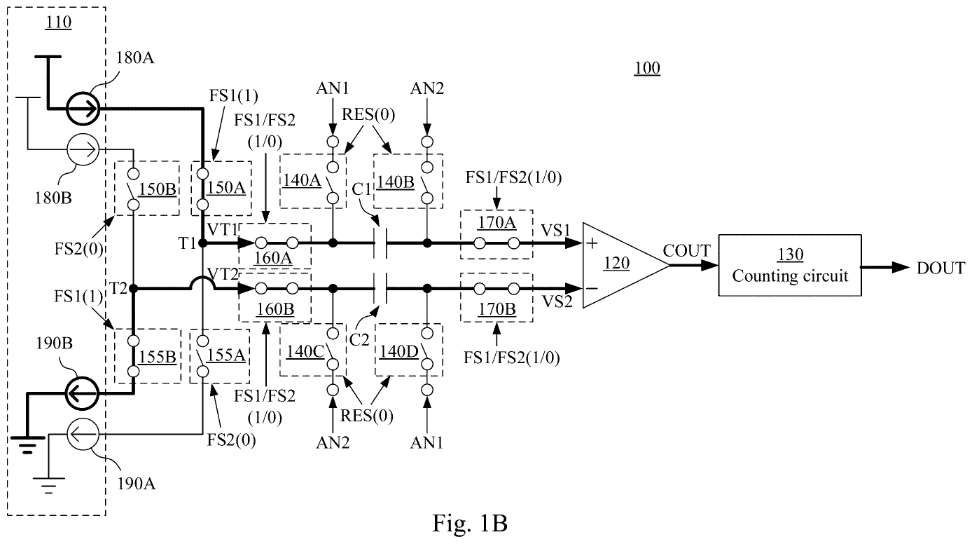

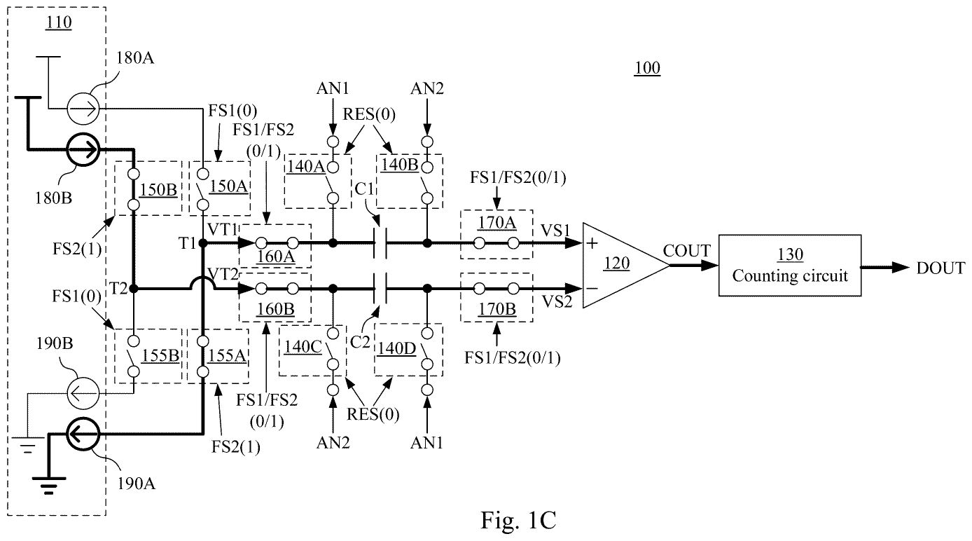

Reference is now made to FIG. 1A to FIG. 1C. FIG. 1A to FIG. 1C illustrate circuit diagrams of a differential slope analog-to-digital conversion apparatus 100 operating under different operation times according to an embodiment of the present invention.

As illustrated in FIG. 1A to FIG. 1C, the differential slope analog-to-digital conversion apparatus 100 includes a first capacitor C1, a second capacitor C2, a ramp voltage generation circuit 110, a comparison circuit 120 and a counting circuit 130.

The differential slope analog-to-digital conversion apparatus 100 may further include a first input switch 140A, a second input switch 140B, a third input switch 140C, a fourth input switch 140D, a first feeding switch 150A, a second feeding switch 150B, a first draining switch 155A, a second draining switch 155B, a first connection switch 160A, a second connection switch 160B, a first comparison switch 170A and a second comparison switch 170B.

In the switches described above, the first input switch 140A, the second input switch 140B, the third input switch 140C and the fourth input switch 140D are controlled by a reset signal RES to be enabled (each being conducted to form a conduction path when being enabled) only when the reset signal RES is at a first state and disabled (each being unconducted to form an open circuit when being disabled) only when the reset signal RES is at a second state.

The first feeding switch 150A and the second draining switch 155B are controlled by a first feeding signal FS1 to be enabled only when the first feeding signal FS1 is at the first state and disabled only when the first feeding signal FS1 is at the second state.

The second feeding switch 150B and the first draining switch 155A are controlled by a second feeding signal FS2 to be enabled only when the second feeding signal FS2 is at the first state and disabled only when the second feeding signal FS2 is at the second state.

The first connection switch 160A, the second connection switch 160B, the first comparison switch 170A and the second comparison switch 170B are simultaneously controlled by the first feeding signal FS1 and the second feeding signal FS2 to be enabled when any one of the first feeding signal FS1 and the second feeding signal FS2 is at the first state and disabled when both of the first feeding signal FS1 and the second feeding signal FS2 are at the second state.

In an embodiment, the first state is a high state and the second state is a low state. For each of the signals in FIG. 1A to FIG. 1C, “1” is labeled thereto indicate the first state, which is the high state, and “0” is labeled thereto indicate the second state, which is the low state. However, the present invention is not limited thereto.

By using the control mechanism of the signals described above, different combinations of the enabling and disabling of the switches in different operation times generate different connection relations among the first capacitor C1, the second capacitor C2, the ramp voltage generation circuit 110 and the comparison circuit 120 illustrated in FIG. 1A to FIG. 1C.

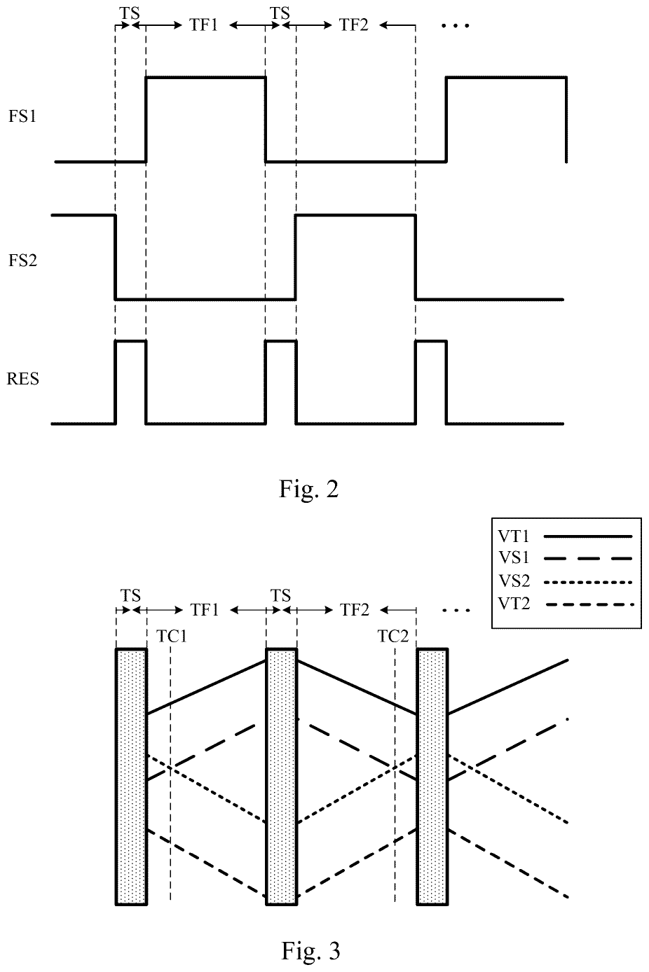

Reference is now made to FIG. 2 at the same time. FIG. 2 illustrates a waveform diagram of signals related to the operation of the differential slope analog-to-digital conversion apparatus 100 in FIG. 1A to FIG. 1C according to an embodiment of the present invention.

More specifically, the states of the reset signal RES, the first feeding signal FS1 and the second feeding signal FS2 in a sampling time TS, a first feeding time TF1 and a second feeding time TF2 are illustrated in FIG. 2. As illustrated in FIG. 2, the first feeding time TF1 and the second feeding time TF2 proceed with the sampling time TS in turn in an interlaced manner. More specifically, the times described above may proceed periodically in the order of the sampling time TS, the first feeding time TF1, the sampling time TS and the second feeding time TF2.

The configuration of the differential slope analog-to-digital conversion apparatus 100 and the operation of the differential slope analog-to-digital conversion apparatus 100 in the sampling time TS, the first feeding time TF1 and the second feeding time TF2 are described in turn in accompany with FIG. 1A to FIG. 1C and FIG. 2. The switches that are enabled and the paths that are enabled due to the enabling of the switches in different times are illustrated with thick lines in FIG. 1A to FIG. 1C.

As illustrated in FIG. 1A, in the sampling time TS, the reset signal RES is at the first state (high state), the first feeding signal FS1 is at the second state (low state) and the second feeding signal FS2 is at the second state (low state).

The first capacitor C1 is configured to perform sampling according to a pair of analog input signals AN1 and AN2 in the sampling time TS. The second capacitor C2 is configured to perform sampling according to the pair of analog input signals AN1 and AN2 in the sampling time TS. In different embodiments, the analog input signals AN1 and AN2 can be a pair of alternating current signals, or may include an alternating current signal and a direct current signal.

More specifically, according the reset signal RES at the first state, the first input switch 140A is configured to be enabled in the sampling time TS to input the first analog input signal of the analog input signals AN1 and AN2 (e.g., the analog input signal AN1) to a first terminal of the first capacitor C1. The second input switch 140B is configured to be enabled in the sampling time TS to input the second analog input signal of the analog input signals AN1 and AN2 (e.g., the analog input signal AN2) to a second terminal of the first capacitor C1.

The third input switch 140C is configured to be enabled in the sampling time TS to input the second analog input signal (e.g., the analog input signal AN2) to a third terminal of second capacitor C2. The fourth input switch 140D is configured to be enabled in the sampling time TS to input the first analog input signal of the analog input signals AN1 and AN2 (e.g., the analog input signal AN1) to the fourth terminal of the second capacitor C2.

On the contrary, in the sampling time TS, the first feeding signal FS1 and the second feeding signal FS2 at the second state controls the first connection switch 160A, the second connection switch 160B, the first comparison switch 170A and the second comparison switch 170B to be disabled such that the two terminals of the first capacitor C1 and the second capacitor C2 are electrically isolated from other circuits.

As a result, the operation of these switches may control the first capacitor C1 and the second capacitor C2 to sample the analog input signals AN1 and AN2.

As illustrated in FIG. 1B, in the first feeding time TF1, the reset signal RES is at the second state (low state), the first feeding signal FS1 is at the first state (high state) and the second feeding signal FS2 is at the second state (low state).

In the first feeding time TF1, the reset signal RES at the second state disables the first input switch 140A, the second input switch 140B, the third input switch 140C and the fourth input switch 140D to prevent the analog input signals AN1 and AN2 from inputting to the first capacitor C1 and the second capacitor C2. Under such a condition, the first capacitor C1 and the second capacitor C2 stop to sample the analog input signals AN1 and AN2.

The ramp voltage generation circuit 110 is configured to perform a positive slope voltage feeding on the first capacitor C1 according to a first positive slope and perform a negative slope voltage feeding on the second capacitor C2 according to a first negative slope in the first feeding time TF1.

In an embodiment, the ramp voltage generation circuit 110 includes a first current feeding circuit 180A, a second current feeding circuit 180B, a first current draining circuit 190A and a second current draining circuit 190B. In FIG. 1A to FIG. 1C, each of the first current feeding circuit 180A, the second current feeding circuit 180B, the first current draining circuit 190A and the second current draining circuit 190B is illustrated as a current source.

According to the first feeding signal FS1 at the first state, the first feeding switch 150A is configured to be enabled only in the first feeding time TF1 to electrically couple the first current feeding circuit 180A and a first connection node T1. The first connection switch 160A is configured to be enabled in the first feeding time TF1 to electrically couple the first connection node T1 to the first terminal of the first capacitor C1. As a result, the first current feeding circuit 180A is configured to be electrically coupled to the first capacitor C1 in the first feeding time TF1 only to feed a current to the first capacitor C1 to perform the positive slope voltage feeding.

According to the first feeding signal FS1 at the first state, the second draining switch 155B is configured to be enabled only in the first feeding time TF1 to electrically couple the second current draining circuit 190B and a second connection node T2. The second connection switch 160B is configured to be enabled in the first feeding time TF1 to electrically couple the second connection node T2 to the third terminal of the second capacitor C2. As a result, the second current draining circuit 190B is configured to be electrically coupled to the second capacitor C2 in the first feeding time TF1 only to drain current from the second capacitor C2 to perform the negative slope voltage feeding.

According to the second feeding signal FS2 at the second state, the second feeding switch 150B and the first draining switch 155A are disabled such that the first connection node T1 and the second connection node T2 are respectively electrically isolated from the second current feeding circuit 180B and the first current draining circuit 190A.

According to the first feeding signal FS1 at the first state, the first comparison switch 170A is configured to be enabled in the first feeding time TF1 to electrically couple the comparison circuit 120 to the second terminal of the first capacitor C1. The second comparison switch 170B is configured to be enabled in the first feeding time TF1 to electrically couple the comparison circuit 120 to the fourth terminal of the second capacitor C2.

Based on the operation described above, the first terminal of the first capacitor C1 is electrically coupled to the ramp voltage generation circuit 110 in the first feeding time TF1 such that the ramp voltage generation circuit 110 performs the positive slope voltage feeding according to the first positive slope. The first terminal of the second capacitor C1 is electrically coupled to the ramp voltage generation circuit 110 in the first feeding time TF1 such that the ramp voltage generation circuit 110 performs the negative slope voltage feeding according to the first negative slope.

The second terminal of the first capacitor C1 and the fourth terminal of second capacitor C2 are both electrically coupled to the comparison circuit 120. As a result, the comparison circuit 120 is configured to receive a first voltage VS1 from the first capacitor C1 and a second voltage VS2 from the second capacitor C2 in the first feeding time TF1 to perform comparison on the first voltage VS1 and the second voltage VS2 to generate a comparison result COUT.

As illustrated in FIG. 1C, in the second feeding time TF2, the reset signal RES is at the second state (low state), the first feeding signal FS1 is at the second state (low state) and the second feeding signal FS2 is at the first state (high state).

The reset signal RES at the second state in the second feeding time TF2 disables the first input switch 140A, the second input switch 140B, the third input switch 140C and the fourth input switch 140D to prevent the analog input signals AN1 and AN2 from inputting to the first capacitor C1 and the second capacitor C2. Under such a condition, the first capacitor C1 and the second capacitor C2 stop to sample the analog input signals AN1 and AN2.

The ramp voltage generation circuit 110 is configured to perform the positive slope voltage feeding on the second capacitor C2 according to a second positive slope and perform a negative slope voltage feeding on the first capacitor C1 according to a second negative slope in the second feeding time TF2.

According to the second feeding signal FS2 at the first state, the second feeding switch 150B is configured to be enabled only in the second feeding time TF2 to electrically couple the second current feeding circuit 180B to the second connection node T2. The second connection switch 160B is configured to be enabled in the second feeding time TF2 to electrically couple the second connection node T2 to the third terminal of the second capacitor C1. As a result, the second current feeding circuit 180B is configured to be electrically coupled to the second capacitor C2 in the second feeding time TF2 only to feed a current to the second capacitor C2 to perform the positive slope voltage feeding.

According to the second feeding signal FS2 at the first state, the first draining switch 155A is configured to be enabled only in the second feeding time TF2 to electrically couple the first current draining circuit 190A to the first connection node T1. The first connection switch 160A is configured to be enabled in the second feeding time TF2 to electrically couple the first connection node T1 to the first terminal of the first capacitor C1. As a result, the first current draining circuit 190A is configured to be electrically coupled to the first capacitor C1 in the second feeding time TF2 only to drain current from the first capacitor C1 to perform the negative slope voltage feeding.

According to the first feeding signal FS1 at the second state, the first feeding switch 150A and the second draining switch 155B are disabled such that the first connection node T1 and second connection node T2 are respectively electrically isolated from the first current feeding circuit 180A and the second current draining circuit 190B.

According to the second feeding signal FS2 at the first state, the first comparison switch 170A is configured to be enabled in the second feeding time TF2 to electrically couple the comparison circuit 120 to the second terminal of the first capacitor C1. The second comparison switch 170B is configured to be enabled in the second feeding time TF2 to electrically couple the comparison circuit 120 to the fourth terminal of the second capacitor C2.

Based on the operation described above, the first terminal of the first capacitor C1 is electrically coupled to the ramp voltage generation circuit 110 in the second feeding time TF2 such that the ramp voltage generation circuit 110 performs negative slope voltage feeding according to the second negative slope. The third terminal of the second capacitor C1 is electrically coupled to the ramp voltage generation circuit 110 in the second feeding time TF2 such that the ramp voltage generation circuit 110 performs the positive slope voltage feeding according to the second positive slope.

The second terminal of the first capacitor C1 and the fourth terminal of the second capacitor C1 are both electrically coupled to the comparison circuit 120. As a result, the comparison circuit 120 is configured to receive the first voltage VS1 from the first capacitor C1 and the second voltage VS2 from the second capacitor C2 in the second feeding time TF2 to perform comparison on the first voltage VS1 and the second voltage VS2 to generate the comparison result COUT.

In an embodiment, the comparison circuit 120 performs subtraction on the first voltage VS1 and the second voltage VS2 to perform the comparison.

Reference is now made to FIG. 3. FIG. 3 illustrates a waveform diagram of a first connection voltage VT1 of the first connection node T1, a second connection voltage VT2 of the second connection node T2, the first voltage VS1 of the second terminal of the first capacitor C1 and the second voltage VS2 of the fourth terminal of the second capacitor C2 in FIG. 1A to FIG. 1C according to an embodiment of the present invention. The first connection voltage VT1 and the second connection voltage VT2 are illustrated independently on different axes. The first voltage VS1 and the second voltage VS2 are together illustrated on one axis.

In accompany with FIG. 3, the variations of each of the voltages in the sampling time TS, the first feeding time TF1 and the second feeding time TF2 are described.

In the sampling time TS, the first feeding switch 150A, the second feeding switch 150B, the first draining switch 155A, the second draining switch 155B, the first connection switch 160A, the second connection switch 160B, the first comparison switch 170A and the second comparison switch 170B are all disabled such that the nodes that the first connection voltage VT1, the second connection voltage VT2, the first voltage VS1 and the second voltage VS2 correspond to are floating. As a result, each of these voltages is at a “don't care” state and is illustrated as a dotted are in FIG. 3.

In the first feeding time TF1, the first connection voltage VT1 and the first voltage VS1 increase according to the first positive slope due to the positive slope voltage feeding performed on the first capacitor C1. The second connection voltage VT2 and the second voltage VS2 decrease according to the first negative slope due to the negative slope voltage feeding performed on the second capacitor C2. Under the condition that the comparison circuit 120 performs subtraction on the first voltage VS1 and the second voltage VS2 to perform comparison, the comparison circuit 120 equivalently performs voltage adjusting according to a first slope that is a first subtraction result of the first positive slope and the first negative slope.

In the second feeding time TF2, the first connection voltage VT1 and the first voltage VS1 decrease according to the second negative slope due to the negative slope voltage feeding performed on the first capacitor C1. The second connection voltage VT2 and the second voltage VS2 increase according to the second positive slope due to the positive slope voltage feeding performed on the second capacitor C2. Under the condition that the comparison circuit 120 performs subtraction on the first voltage VS1 and the second voltage VS2 to perform comparison, the comparison circuit 120 equivalently performs voltage adjusting according to second slope that is a second subtraction result of the second negative slope and the second positive slope.

In an embodiment, each of the absolute values of the first positive slope, the second positive slope, the first negative slope and the second negative slope equals to a slope value such that the comparison circuit 120 equivalently receives a ramp voltage of two times of such a slope value. However, the present invention is not limited thereto.

The counting circuit 130 is configured to perform counting according to the comparison result COUT to generate a digital output signal DOUT. In an embodiment, at the time spots that the first voltage VS1 and the second voltage VS2 meets at the same voltage value, e.g., the time spot TC1 in the first feeding time TF1 and the time spot TC2 in the second feeding time TF2, the counting circuit 130 finishes performing counting and outputs the counting result as the digital output signal DOUT.

For the analog-to-digital apparatus that generates the digital signal by comparing the input signal and the ramp signal and performing counting based on the comparison result, the required slope is steep when the time required for the ramp signal to reach a certain level is too short, such that the design complexity of a ramp signal generation circuit used in the slope analog-to-digital conversion apparatus increases.

The differential slope analog-to-digital conversion apparatus of the present invention operates in a differential form such that two terminals of the comparison circuit receive the ramp voltages respectively having a positive slope and a negative slope to obtain an equivalently larger slope to allow the analog input signals approximating each other accordingly. The design complexity of a ramp voltage generation circuit can therefore be reduced.

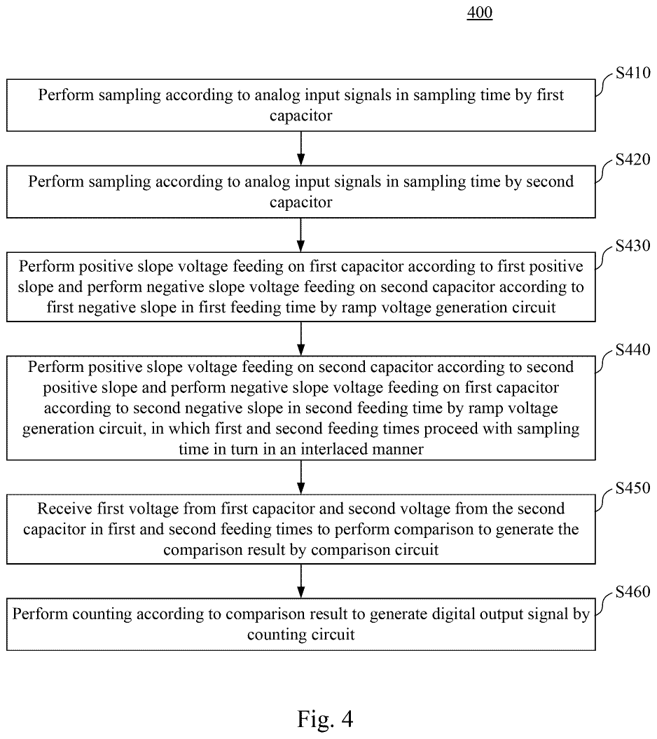

Reference is now made to FIG. 4. FIG. 4 illustrates a flow chart of a differential slope analog-to-digital conversion method 400 according to an embodiment of the present invention.

In addition to the apparatus described above, the present disclosure further provides the differential slope analog-to-digital conversion method 400 that can be used in such as, but not limited to, the differential slope analog-to-digital conversion apparatus 100 in FIG. 1. As illustrated in FIG. 4, an embodiment of the differential slope analog-to-digital conversion method includes the following steps.

In step S410, sampling is performed according to the pair of analog input signals AN1 and AN2 in the sampling time by the first capacitor C1.

In step S420, sampling is performed according to the pair of analog input signals AN1 and AN2 in the sampling time by the second capacitor C2.

In step S430, the positive slope voltage feeding is performed on the first capacitor C1 according to the first positive slope and the negative slope voltage feeding is performed on the second capacitor C2 according to the first negative slope in the first feeding time TF1 by the ramp voltage generation circuit 110.

In step S440, the positive slope voltage feeding is performed on the second capacitor C2 according to the second positive slope and the negative slope voltage feeding is performed on the first capacitor C1 according to the second negative slope in the second feeding time TF2 by the ramp voltage generation circuit 110, in which the first feeding time TF1 and the second feeding time TF2 proceed with the sampling time TS in turn in an interlaced manner.

In step S450, the first voltage VS1 is received from the first capacitor C1 and the second voltage VS2 is received from the second capacitor C2 in the first feeding time TF1 and the second feeding time TF2 to perform comparison to generate the comparison result COUT by the comparison circuit 120.

In step S460, counting is performed according to the comparison result COUT to generate the digital output signal DOUT by the counting circuit 130.

It is appreciated that the embodiments described above are merely an example. In other embodiments, it should be appreciated that many modifications and changes may be made by those of ordinary skill in the art without departing, from the spirit of the disclosure. For example, the configuration that uses the switches to be enabled and disabled according to the corresponding control timings such that the differential slope analog-to-digital conversion apparatus samples the analog input signals and feeds the ramp voltages accordingly is merely an example. In other embodiments, other mechanisms, other disposition topologies of the switches and other timing control mechanisms can be used to perform the sampling of the analog input signals and the feeding of the ramp voltages. The present invention is not limited to a certain circuit configuration.

In summary, the present invention discloses the differential slope analog-to-digital conversion apparatus and a differential slope analog-to-digital conversion method operate in a differential form such that two terminals of a comparison circuit receive ramp voltages respectively having a positive slope and a negative slope to obtain an equivalently larger slope to allow analog input signals approximating each other accordingly. The design complexity of a ramp voltage generation circuit can therefore be reduced.

The aforementioned descriptions represent merely the preferred embodiments of the present invention, without any intention to limit the scope of the present invention thereto. Various equivalent changes, alterations, or modifications based on the claims of present invention are all consequently viewed as being embraced by the scope of the present invention.

What is claimed is:

1. A differential slope analog-to-digital conversion apparatus, comprising:
a first capacitor configured to perform sampling according to a pair of analog input signals in a sampling time;
a second capacitor configured to perform sampling according to the pair of analog input signals in the sampling time;
a ramp voltage generation circuit configured to:
perform a positive slope voltage feeding on the first capacitor according to a first positive slope and perform a negative slope voltage feeding on the second capacitor according to a first negative slope in a first feeding time; and
perform the positive slope voltage feeding on the second capacitor according to a second positive slope and perform the negative slope voltage feeding on the first capacitor according to a second negative slope in a second feeding time, in which the first feeding time and the second feeding time proceed with the sampling time in turn in an interlaced manner;
a comparison circuit configured to receive a first voltage from the first capacitor and a second voltage from the second capacitor in the first feeding time and the second feeding time to perform comparison to generate a comparison result; and
a counting circuit configured to perform counting according to the comparison result to generate a digital output signal.

2. The differential slope analog-to-digital conversion apparatus of claim 1, further comprising:
a first input switch configured to input a first analog input signal of the pair of analog input signals to a first terminal of the first capacitor in the sampling time, wherein the first terminal of the first capacitor is electrically coupled to the ramp voltage generation circuit in the first feeding time and the second feeding time;
a second input switch configured to input a second analog input signal of the pair of analog input signals to a second terminal of the first capacitor in the sampling time, wherein the second terminal of the first capacitor is electrically coupled to the comparison circuit in the first feeding time and the second feeding time;
a third input switch configured to input the second analog input signal to a third terminal of the second capacitor in the sampling time, wherein the third terminal of the second capacitor is electrically coupled to the ramp voltage generation circuit in the first feeding time and the second feeding time; and
a fourth input switch configured to input the first analog input signal to a fourth terminal of the second capacitor in the sampling time, wherein the fourth terminal of the second capacitor is electrically coupled to the comparison circuit in the first feeding time and the second feeding time.

3. The differential slope analog-to-digital conversion apparatus of claim 1, wherein the ramp voltage generation circuit further comprises:
a first current feeding circuit electrically coupled to the first capacitor only in the first feeding time to perform current feeding on the first capacitor, so as to perform the positive slope voltage feeding;
a second current feeding circuit electrically coupled to the second capacitor only in the second feeding time to perform current feeding on the second capacitor, so as to perform the positive slope voltage feeding;
a first current draining circuit electrically coupled to the first capacitor only in the second feeding time to perform current draining on the first capacitor, so as to perform the negative slope voltage feeding; and
a second current draining circuit electrically coupled to the second capacitor only in the first feeding time to perform current draining on the second capacitor, so as to perform the negative slope voltage feeding.

4. The differential slope analog-to-digital conversion apparatus of claim 3, further comprising:
a first feeding switch configured to electrically couple the first current feeding circuit and a first connection node only in the first feeding time;
a second feeding switch configured to electrically couple the second current feeding circuit and a second connection node only in the second feeding time;
a first draining switch configured to electrically couple the first current draining circuit and the first connection node only in the second feeding time;
a second draining switch configured to electrically couple the second current draining circuit and the second connection node only in the first feeding time;
a first connection switch configured to electrically couple the first connection node to a first terminal of the first capacitor in the first feeding time and the second feeding time; and
a second connection switch configured to electrically couple the second connection node to a third terminal of the second capacitor in the first feeding time and the second feeding time.

5. The differential slope analog-to-digital conversion apparatus of claim 4, further comprising:
a first comparison switch configured to electrically couple the comparison circuit to a second terminal of the first capacitor in the first feeding time and the second feeding time; and
a second comparison switch configured to electrically couple the comparison circuit to a fourth terminal of the second capacitor in the first feeding time and the second feeding time.

6. The differential slope analog-to-digital conversion apparatus of claim 1, wherein the pair of analog input signals are a pair of alternating current signals.

7. The differential slope analog-to-digital conversion apparatus of claim 1, wherein the pair of analog input signals comprises an alternating current signal and a direct current signal.

8. The differential slope analog-to-digital conversion apparatus of claim 1, wherein the comparison circuit performs subtraction on the first voltage and the second voltage to equivalently perform voltage adjusting according to a first slope that is a first subtraction result of the first positive slope and the first negative slope in the first feeding time, and to equivalently perform voltage adjusting according to a second slope that is a second subtraction result of the second negative slope and the second positive slope in the second feeding time.

9. A differential slope analog-to-digital conversion method, comprising:
performing sampling according to a pair of analog input signals in a sampling time by a first capacitor;
performing sampling according to the pair of analog input signals in the sampling time by a second capacitor;
performing a positive slope voltage feeding on the first capacitor according to a first positive slope and performing a negative slope voltage feeding on the second capacitor according to a first negative slope in a first feeding time by a ramp voltage generation circuit;
performing the positive slope voltage feeding on the second capacitor according to a second positive slope and performing the negative slope voltage feeding on the first capacitor according to a second negative slope in a second feeding time by the ramp voltage generation circuit, in which the first feeding time and the second feeding time proceed with the sampling time in turn in an interlaced manner;
receiving a first voltage from the first capacitor and a second voltage from the second capacitor in the first feeding time and the second feeding time to perform comparison to generate a comparison result by a comparison circuit; and
performing counting according to the comparison result to generate a digital output signal by a counting circuit.

10. The differential slope analog-to-digital conversion method of claim 9, further comprising:
inputting a first analog input signal of the pair of analog input signals to a first terminal of the first capacitor in the sampling time by a first input switch, wherein the first terminal of the first capacitor is electrically coupled to the ramp voltage generation circuit in the first feeding time and the second feeding time;
inputting a second analog input signal of the pair of analog input signals to a second terminal of the first capacitor in the sampling time by a second input switch, wherein the second terminal of the first capacitor is electrically coupled to the comparison circuit in the first feeding time and the second feeding time;
inputting the second analog input signal to a third terminal of the second capacitor in the sampling time by a third input switch, wherein the third terminal of the second capacitor is electrically coupled to the ramp voltage generation circuit in the first feeding time and the second feeding time; and
inputting the first analog input signal to a fourth terminal of the second capacitor in the sampling time by a fourth input switch, wherein the fourth terminal of the second capacitor is electrically coupled to the comparison circuit in the first feeding time and the second feeding time.

11. The differential slope analog-to-digital conversion method of claim 9, further comprising:
electrically coupling a first current feeding circuit of the ramp voltage generation circuit to the first capacitor only in the first feeding time to perform current feeding on the first capacitor, so as to perform the positive slope voltage feeding;
electrically coupling a second current feeding circuit of the ramp voltage generation circuit to the second capacitor only in the second feeding time to perform current feeding on the second capacitor, so as to perform the positive slope voltage feeding;
electrically coupling a first current draining circuit of the ramp voltage generation circuit to the first capacitor only in the second feeding time to perform current draining on the first capacitor, so as to perform the negative slope voltage feeding; and
electrically coupling a second current draining circuit of the ramp voltage generation circuit to the second capacitor only in the first feeding time to perform current draining on the second capacitor, so as to perform the negative slope voltage feeding.

12. The differential slope analog-to-digital conversion method of claim 11, further comprising:
electrically coupling the first current feeding circuit and a first connection node only in the first feeding time by a first feeding switch;
electrically coupling the second current feeding circuit and a second connection node only in the second feeding time by a second feeding switch;
electrically coupling the first current draining circuit and the first connection node only in the second feeding time by a first draining switch;
electrically coupling the second current draining circuit and the second connection node only in the first feeding time by a second draining switch;
electrically coupling the first connection node to a first terminal of the first capacitor in the first feeding time and the second feeding time by a first connection switch; and
electrically coupling the second connection node to a third terminal of the second capacitor in the first feeding time and the second feeding time by a second connection switch.

13. The differential slope analog-to-digital conversion method of claim 12, further comprising:
electrically coupling the comparison circuit to a second terminal of the first capacitor in the first feeding time and the second feeding time by a first comparison switch; and
electrically coupling the comparison circuit to a fourth terminal of the second capacitor in the first feeding time and the second feeding time by a second comparison switch.

14. The differential slope analog-to-digital conversion method of claim 9, wherein the pair of analog input signals are a pair of alternating current signals.

15. The differential slope analog-to-digital conversion method of claim 9, wherein the pair of analog input signals comprises an alternating current signal and a direct current signal.

16. The differential slope analog-to-digital conversion method of claim 9, further comprising:
performing subtraction on the first voltage and the second voltage by the comparison circuit to equivalently perform voltage adjusting according to a first slope that is a first subtraction result of the first positive slope and the first negative slope in the first feeding time, and to equivalently perform voltage adjusting according to a second slope that is a second subtraction result of the second negative slope and the second positive slope in the second feeding time.
